(19) United States
(12) Patent Application Publication
(10) Pub. No.: US 2005/0111676 A1
(43) Pub. Date: May 26, 2005

(54) System panel programmer apparatus and method

(75) Inventors: Raymond J. LeBlanc, Bristol, CT (US); Angelo S. Arcaria, Wethersfield, CT (US)

Correspondence Address: BAKER & HOSTETLER LLP;Washington Square, Suite 1100, 1050 Connecticut Avenue, N.W., WASHINGTON, DC, 20036, US

(73) Assignee: Edwards Systems Technology, Inc.

(21) Appl. No.: 10/722,096

(22) Filed: Nov. 26, 2003

(51) Int. Cl. H03F 21/00; G06F 17/00

(52) U.S. Cl. 381/120; 700/94

(57) ABSTRACT

A software-based initialization method allows a user to initialize a speaker amplifier system panel rapidly and reliably. An inventive routine uses a personal computer to generate the command sequences required for a master system panel and any number of satellite and extended satellite system panels configured at user option, allowing previously determined features of the speaker amplifier system to be accommodated without reference to procedure charts or lookup tables. The improved method reduces training time and avoids error-prone manual initialization procedures.

### FIELD OF THE INVENTION

The present invention relates generally to paging, signaling, and annunciator systems. More particularly, the invention relates to automated initialization of paging and signaling.

### BACKGROUND OF THE INVENTION

Annunciator and paging systems within such facilities as factories, office buildings, parks, schools, and the like can use electrically activated and/or controlled sound generators such as bells as well as speaker-generated tones to announce normal periodic events such as breaks, shift changes, and other non-emergency events. Similar devices can be used for fire and evacuation alarms and other emergency events. Such systems are commonly limited to a single sound, in the case of those using mechanical bells, for example, and a range of sounds, in the case of systems that use speakers and are driven from a separate audio tone source.

Some paging, signaling, and annunciator system designs use an individual loudspeaker at each of a multiplicity of locations. In some versions, they are wired in parallel; each speaker may be transformer-isolated to permit high transmitter signal voltage at low current, which can reduce copper losses. Other designs may use signals sent from a central source at comparatively low levels, for which designs speaker amplifiers may be equipped with power supplies driven by local AC or DC power. Systems may have multiple zones to be signaled at different times or under different circumstances; these systems may be directly wired by zone from a shared control panel. Speaker amplifiers wired individually back to a control panel may be activated individually using switches. Volume control may be realized using a central attenuator or an attenuator at each speaker or speaker amplifier.

In addition to analog speaker amplifier systems of the types indicated above, digitally enabled speaker amplifier systems can be made, which can include direct addressing of individual digitally enabled speaker amplifiers through a signal distribution system from a speaker amplifier system panel, so that the individual speaker amplifiers can recognize their own addresses and respond appropriately. Conventional digitally enabled speaker systems can typically employ RS-485, which is a standard recognized by the Electronics Industry Association (EIA). RS-485 is a two-wire transmission line communication bus that uses a differential serial data stream for communication between one talker at a time and multiple listeners. Speaker systems that use RS-485 are typically programmed by manually entering, via a keypad on a system panel, a series of largely identical command strings, differing primarily in address, and built up from a simple character set, such as the hexadecimal numbers.

Systems of the types described have been limited previously to manual operation of the system configuration task, which can be time-consuming and error-prone in complex installations. The difficulty of configuration of such systems can in turn drive system architecture and even safety decisions concerning the degree to which complexity may be designed in, so that a useful and practical, but complex, system may be avoided in preference to a less useful but less complex system.

Therefore, it would be desirable to have a speaker amplifier system with simplified and automated configuration capability and increased configuration flexibility, such as by incorporating computer technology to a greater extent than has been done heretofore.

### SUMMARY OF THE INVENTION

The forgoing needs are met, to a great extent, by the present invention, which in some embodiments provides a software-based control system for speaker amplifier system panels, which software-based system may be installed, for example, on a personal computer and connected to at least one speaker amplifier system panel able to receive and transmit digital control transmissions. A preferred embodiment of the present invention presents a graphical status display representing the properties of each speaker amplifier system panel and each digitally addressable speaker amplifier. For example, the system state can be ascertained for each system panel and each digitally addressable speaker amplifier, displayed in a visual summary, and stored using any appropriate storage technology. Setup activity to configure speaker amplifier system panels, both for tones and for audio signals such as voice and radio, can configure speaker amplifier system panels for output individually, and, through the speaker amplifier system panels, can configure digitally addressable speaker amplifiers as well. The software-based interface allows for system expansion including direct communication with individual speaker amplifier system panels.

In one aspect, an automation system for speaker amplifier setup comprises a set of commands that implement setup functions within a speaker amplifier system, a speaker amplifier system panel capable of executing the set of instructions, and a set of speaker amplifiers electrically connected to and controlled by the speaker amplifier system panel.

In another aspect, an automation system for speaker amplifier setup comprises means for processing electronic signals, means for communicating between the processing means and a speaker amplifier system panel, and means for configuring the speaker amplifier system panel in response to signals from the processing means.

In yet another aspect, a method for configuring a speaker amplifier system panel comprises the steps of executing a configuration status acquisition routine, executing a configuration status report generator, executing a configuration status display routine, generating a display output that represents the acquired configuration status report, generating a configuration change command, and executing a command transmittal to a speaker amplifier system panel.

There have thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is an overall interconnection diagram of a speaker amplifier system according to this invention.

FIG. 2 is a command list for the revised System Panel.

FIG. 3 is a flowchart of an exemplary process of this invention.

FIG. 4 is an exemplary view of an initial screen.

FIG. 5 is an exemplary view of a screen during download.

FIG. 6 is an exemplary view of a relay assignment screen.

FIG. 7 is an exemplary view of a device commissions screen during upload.

### DETAILED DESCRIPTION

The invention will now be described with reference to the drawing figures, in which like reference numerals refer to like parts throughout. Embodiments in accordance with the present invention provide a method and apparatus for configuring at least one control panel in a speaker amplifier system controlled by a control processor. It should be appreciated that the devices termed annunciators and speaker amplifiers are typically differentiated by the presence either of tone generation, with or without voice recording capability, in which case the device is termed an annunciator, or of analog audio input amplification capability, in which case the device is termed a speaker amplifier. Each of the device types can be configured to communicate with other system elements, for example through RS-485 connections, although so-called dumb speaker amplifiers may accept only analog input and may lack digital interface capability. The term speaker amplifier will be used herein in reference to the device styles to which the present invention is applicable.

Hardware and software for remote and/or dynamic configuration of speaker amplifier and annunciator systems suitable for facilitating some of the functions described herein are detailed in copending applications, “Programmable Event Driver/Interface Apparatus and Method,” U.S. patent application Ser. No. 10/664,911, by LeBlanc et al., filed Sep. 22, 2003, and “System Panel Programmer Apparatus and Method,” by LeBlanc et al., filed Nov. 20, 2003, the contents of which are incorporated herein by reference in their entirety.

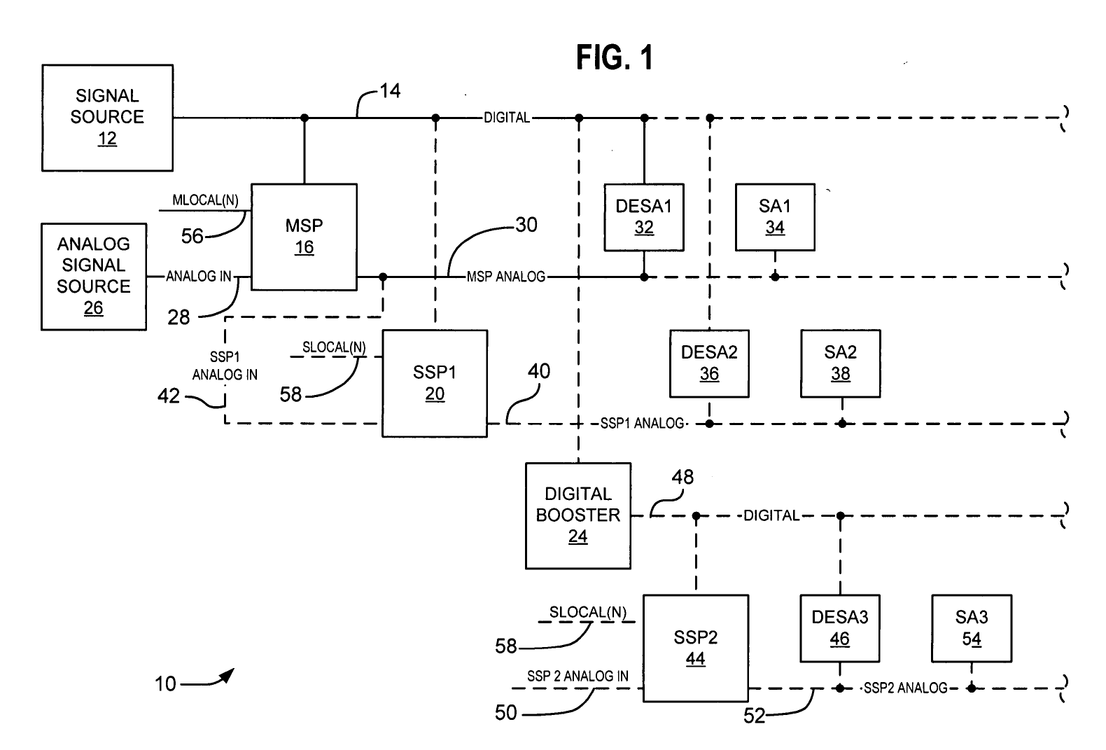

FIG. 1 is a block diagram illustrating an exemplary embodiment of a speaker amplifier configuration control system 10. The exemplary configuration control system 10 comprises a signal source 12 that can produce an output on a digital line 14, which can be, in the exemplary system 10, connected to a Master System Panel (MSP) 16 and at least one First Digitally Enabled Speaker Amplifier (DESA1) 32. The digital line 14 is optionally connected to one or more First Satellite System Panels (SSP1s) 20, one or more Digital Boosters 24, and one or more Second Digitally Enabled Speaker Amplifiers (DESA2s) 36 depending from SSP1's 20. The MSP 16 may be fed from an Analog Signal Source 26 by way of an analog input line 28, and may normally provide output via an analog output line 30, from which it can feed the analog input of at least one DESA1 32. The analog output line 30 may optionally feed one or more analog-only First Speaker Amplifiers (SA1s) 34 as described in the preceding paragraph, as well as DESA1s 32. Similarly, the SSP1s 20 may feed one or more DESA2s 36 and Second Speaker Amplifiers (SA2s) 38, sharing, in the exemplary system 10, the same digital input line 14, but using a separate SSP1 analog output line 40.

In the exemplary system 10, a branch from the MSP analog output line 30 serves as the SSP1 analog input line 42 feeding an SSP1 20. The Digital Booster 24 may drive its own suite of Second Satellite System Panels (SSP2s) 44 as well as its own Digitally Enabled Speaker Amplifiers (DESA3s) 46 by way of the Digital Booster 24's digital output line 48. If the SSP2s 44 fed from the Digital Booster 24 receive analog input 50, they may include an analog output feed line 52 into the DESA3s 46 and Third Speaker Amplifiers (SA3s) 54 of the system architecture extending beyond the Digital Booster 24. The foregoing is a representative digital and analog signal distribution configuration for an exemplary system 10; other configurations may be preferable for specific applications. It will be appreciated that an embodiment in accordance with the inventive apparatus and method can use all DESAs, all SAs, or a combination of the two device types.

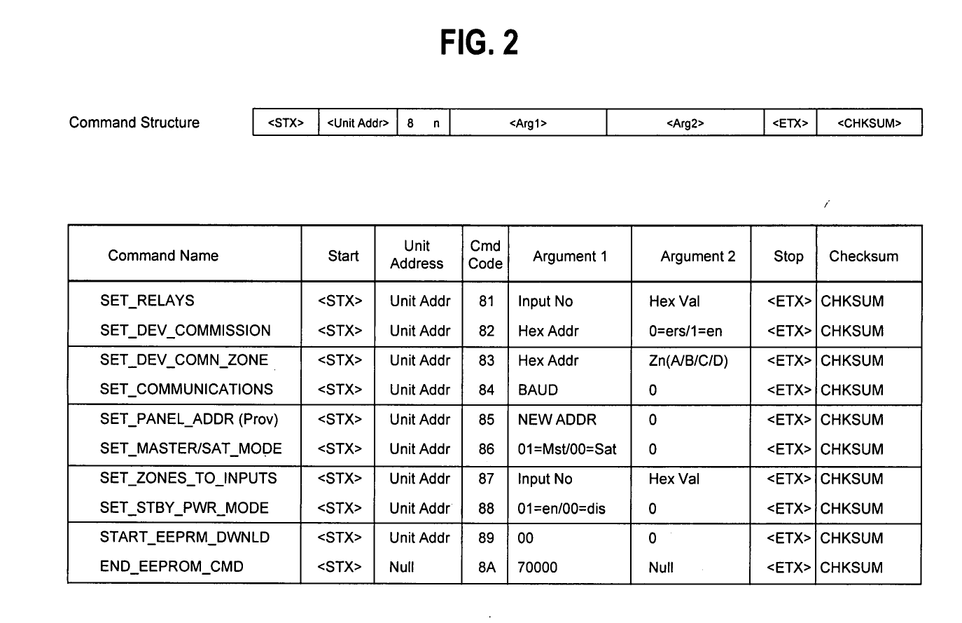

FIG. 2 is a table illustrating an extended command set suitable for control of the exemplary control system 10. These commands are identified and distinguished by command codes 81 (hex) through 8A (hex). The commands are labeled with self-descriptive titles and may, upon the function being invoked, use arguments for command or data passing. These commands or an equivalent set can add sufficient functionality to an MSP 16 to support automated configuration setup. It should be appreciated that the list of commands displayed in FIG. 2 is presented as a sample representative of the commands available for controlling the exemplary control system 10. Other or additional commands may be generated without departing from the sprit and scope of this invention.

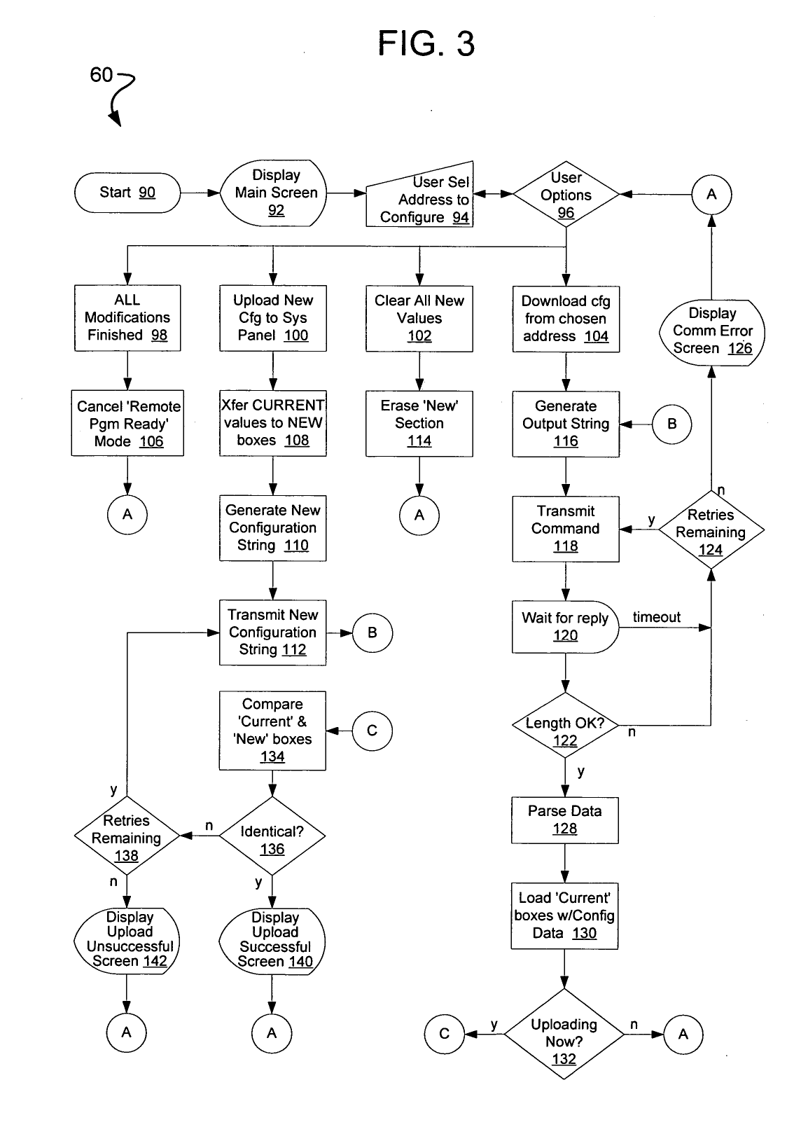

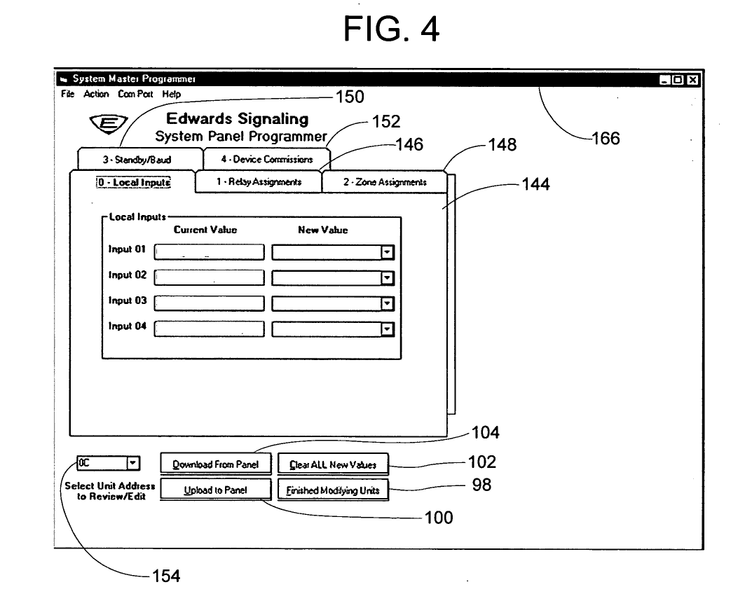

FIG. 3 is a flowchart illustrating an exemplary process 60 leading to a fully setup MSP 16. The process 60 operating within the signal source 12 to direct the setup of the MSP 16 includes a command routine, a monitor routine, a system status report generator, and a configuration status display routine for generating a display output, as described below. Following initialization of the signal source 12 in an exemplary system 10 wherein the exemplary process 60 has been installed, the MSP 16 setup process 60 can be invoked 90. Startup of the exemplary process 60 can include display 92 of a main screen, the appearance of which is illustrated in FIG. 4, that allows the user to issue commands by clicking on soft buttons using a mouse or equivalent pointing device, or by using keystrokes, such as, for example, holding down the keyboard's “ALT” key and pressing a designated alphanumeric key. The first of the available functions shown in the exemplary process 60 can be the user selection of a device to be configured 94. As shown in FIG. 3, this choice can allow access to a menu of user options 96. The selection from among user options 96 can include an “end-of-operation” selection 98, an “upload” selection 100 for transmitting a new configuration for the MSP 16, a “clear new values” selection 102 to cancel an in-process configuration change, and a “download” selection 104 to allow the signal source 12 to acquire previous settings from the MSP 16.

Choosing the end-of-operation selection 98 leads to cancellation 106 of the remote programming ready mode when the signal source 12 is being used to examine or modify system configuration, and returns the exemplary process 60 to the state where choice of a user option 96 is awaited. This step leaves the work screen active, but allows the MSP 16 to resume polling and other interactions with DESAs 32, 36, and 46 on its own, and can be followed by more configuration commands only if the MSP 16 front-panel suspension of normal operation is reinvoked.

Selection of the upload command 100 causes the present configuration, including any newly set configuration items, to be sent to the device address previously chosen 94. The command does this by causing any unchanged, that is, current, entries stored in the controller to be transferred to outgoing—i.e., new data—locations 108, then using the now-configured content of the new data locations to develop a new configuration string 110.

The new configuration string 110 can then be transferred 112 to the transmission section of the software, at connection node B of the flowchart, where a complete output string can be put together 116 using invariant elements, such as, for example, start and stop bits, and varying elements, such as checksum bits, along with the outgoing command information comprising the new configuration string 110. Next, the complete output string 116 can be transmitted 118 in accordance with the interconnection diagram, FIG. 1.

The new configuration string 110 transmission process can continue, and can include a system hold function 120—that is, a timeout-limited loop that can be interrupted to resume normal operation—to await a reply. If the reply comes back before a timeout occurs and execution resumes, then the reply is first tested for length 122, i.e., the number of bits in the response is compared to the allowable length for that response. If the length is wrong, as might happen, for example, if the MSP 16 were defective or missing, or if excessive noise interfered with reception in either direction, then a loopback 124 permits the transmission to be repeated a specified number of times. Failure after a number of attempts can result in display of an error message 126 and termination of the setup routine for that session. If the reply fails to come back before a timeout occurs 120, then the above loopback 124 permits a preselected number of attempts to be followed by termination with error messaging 126.

Successful reception of a reply of the correct length 122 in one of the allowed transmission attempts permits parsing 128 for content of the reply signal from the system. The principal content of the reply signal is the current configuration of the selected device, namely, the configuration after reception and execution of the new configuration string 110. Execution of the remainder of the new configuration string by the selected device in an exemplary system can precede reply transmission by the selected device.

The captured and parsed 128 content is transferred to storage locations, here termed “boxes”, for display and use 130, after which the immediate status of the routine, namely, whether uploading is in progress, is reviewed 132. If uploading is in progress, then the process 60 jumps to a routine for verifying that the “as commanded” and “as implemented and reported” box contents are equivalent 134. If they are equivalent 136, then a displayed message confirms the success 140, and the routine halts to allow another task to be performed by jumping through the user option branch 96 to the user select address task 94. If not equivalent, then the availability of additional retries is determined 138. If permitted, transmission is reattempted 112 as above; if retries are over, then an error message is displayed 142 and the routine jumps to the beginning of the user option 96 and user address select task 94 to await the next command.

The exemplary process 60 waits indefinitely in any branch state until a choice between options is made by a user or a quit option is chosen. This is illustrated in FIG. 4, which is a screen shot illustrating the appearance of an exemplary display during a waiting, non-error condition. The screen shot shows the four user options 98, 100, 102, and 104 as graphical pushbuttons with the same notation. In the state shown, no options have yet been selected, and the five tabs 144, 146, 148, 150, and 152 are in their default orientation. The process 60 permits selection of one unit at a time with the Select Unit field 154; for the example shown, the unit numbered 0C(hex) has been selected.

FIG. 4 further shows the top bar 166, which can be presented in a style conventional to GUI software. Application of input data to the exemplary selected tab 144 may require selection of a data field, such as by positioning a cursor on the desired field by way of a mouse, then activating (in some GUI systems, this employs a so-called point-and-click interface); other methods such as use of a tab key, up and down arrow keys, or a sequence such as the “ALT” key followed by an alphanumeric key may be similarly employed for such positioning. Activation of a “soft” button 98, 100, 102, or 104 may be accomplished by the point-and-click method described for positioning or by an equivalent method, such as pressing the space bar or return key on the keyboard while a soft button is selected.

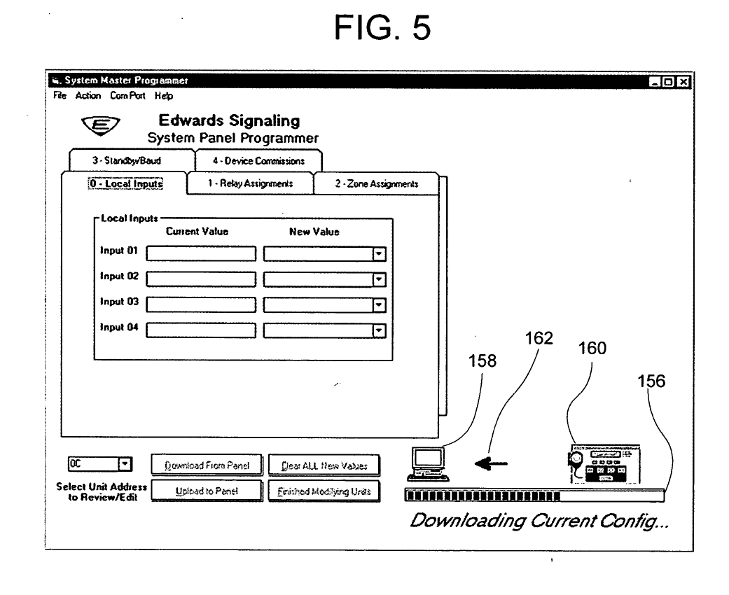

FIG. 5 is a screen shot showing the change in exemplary screen appearance after actuation of the download from the soft button 104. A progress bar 156 is shown, along with a representation of the device 158 in which the exemplary process 60 resides, the target device 160 to which the command to download has been directed, and a flow direction symbol 162. The command causes download of the parameters for a single unit.

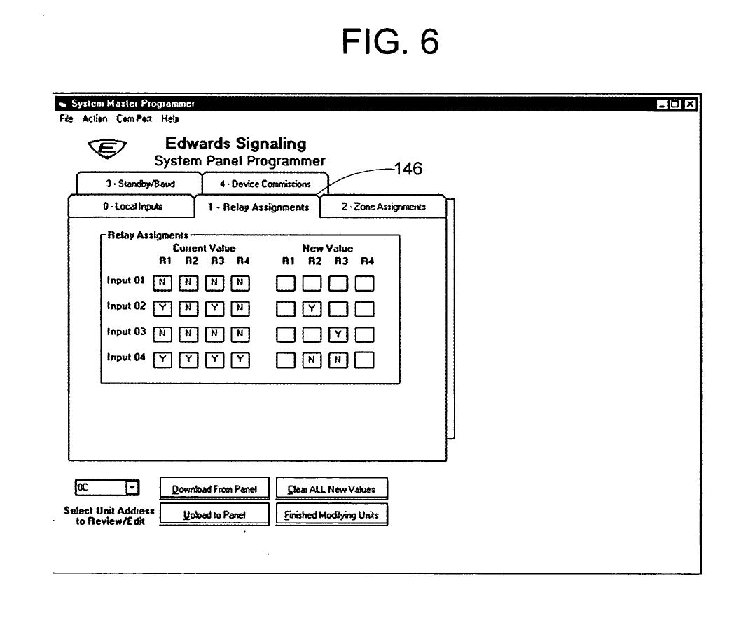

FIG. 6 is a screen shot showing an exemplary screen used to set some of the parameters of an MSP 16 from the exemplary process 60. Here, the tab for relay assignments 146 is accessed to permit changes to be installed therein.

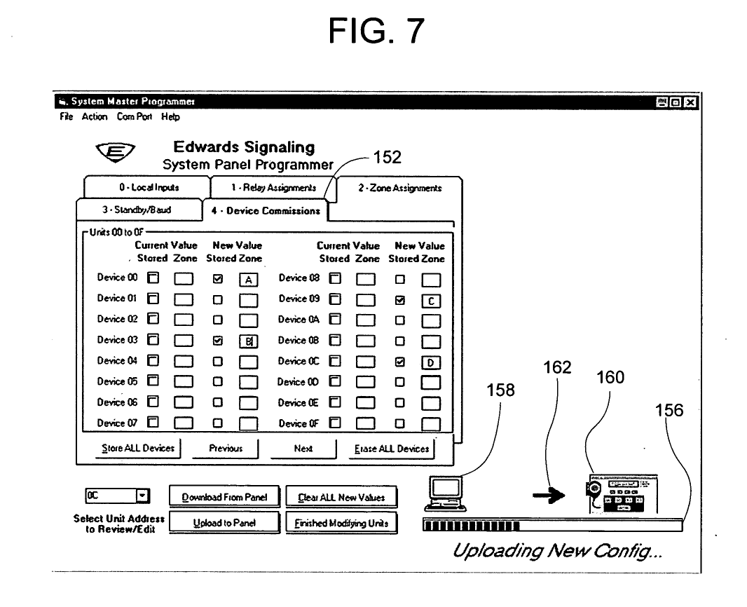

FIG. 7 is an exemplary screen shot whereon the “device commissions” tab 152 is active. This screen is shown during upload of the data from the signal source 12 to its target device, the MSP 16. The “device commissions” function as defined for an MSP 16 is the assignment of each DESA1 32, DESA2 36, or DESA3 46 to a zone, which assignment modifies the configuration of the MSP 16 without modifying the DESA1 32, DESA2 36, or DESA3 46 itself. The first icon 158 again shows the signal source 12 on which the exemplary process 60 resides, while the second icon 160 represents the target device, in this case an MSP 16 compatible with the exemplary process 60. As in FIG. 5, an animated arrow 162 moves to indicate direction of data flow, and a progress bar 156 shows in graphic form an approximation of the time remaining until the processing of the current activity is complete.

Setting up an MSP 16 according to the preferred embodiment can represent a significant change when compared to previous Master System Panel setup processes. Prior-art programming routines for speaker amplifier systems, as executed from the MSPs themselves, are, for all purposes, entirely manual. Manual-only programming routines for Master System Panels are in many instances virtually entirely lacking the record keeping, dynamic configuration control, and user training and support functions that are intrinsic capabilities of systems using graphics-oriented programming routines for System Panels.

Alternative signal source 12 hardware for setup of Master System Panels may take different physical form in some embodiments of the invention. Hardware may take the form of an off-the shelf personal computer, or alternatively may have features such as placement of the equivalent of an off-the-shelf personal computer's electronics in a rack-mounted or panel-mounted configuration. Alternative hardware configurations can feature a variety of user interface styles, as well, such as a free-standing, suspended, or embedded display; touch screen interface in lieu of or in addition to a mouse, trackball, joystick, touchpad, or other graphical indicator positioning device; and/or a keyboard that can be free-standing, suspended, drawer mounted, fold-out, or flush on a panel. Audio output for a user at the signal source 12 location can be implemented with speakers, headphone jacks, or equivalent apparatus.

While the signal source 12 may use a transceiver for communicating with a digital line, such as, for example, an RS-485 line, other implementations, which may include an RS-232 port within a personal computer driving an external RS-232 to RS-485 converter, as well as styles of converters that accept and convert non-RS-232 inputs, such as USB to RS-485 converters, may be suitable for some preferred system configurations. While RS-485 is used as the output format in the preferred embodiment, other communications standards, such as IEEE-802, which includes Ethernet®, and which standards preferably incorporate one or more pairs of differential signal lines, can be employed. Technologies other than electronic signals over copper conductors can likewise be used, such as fiber optics, radio transmissions, and modulation on power lines, each of which may incur limitations of bandwidth and reliability.

Detection and localization of at least some classes of failures in speaker amplifier systems that manifest during MSP 16 setup can be accelerated by the exemplary systems and methods herein when compared to manual systems. Normal and routine operations include polling of all devices external to the signal source 12 and MSP 16, for example, with any inconsistencies highlighted at the time they first occur.

System setup and user training can each be performed offline, permitting avoidance of workplace distractions such as unexpected tones sounding during the workday.

The many features and advantages of the invention are apparent from the detailed specification, and, thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described; accordingly, all suitable modifications and equivalents may be resorted to that fall within the scope of the invention.

1. An automation system for speaker amplifier setup, comprising:
a computer-readable storage medium containing a set of commands that implement speaker amplifier system panel setup functions;
a signal source capable of transmitting command signals conforming to the command set contained on said computer-readable storage medium;
a speaker amplifier system panel capable of executing said set of commands; and
a functional element of said speaker amplifier system panel capable of receiving said command signals.

2. The automation system for speaker amplifier setup of claim 1, wherein said signal source further comprises:
a human interface subsystem supporting command and configuration input and display for said control processor unit;
a nonvolatile storage subsystem storing and retrieving data on behalf of said signal source unit; and
a communications subsystem establishing a communication link between said speaker amplifier system panel and said signal source.

3. The automation system for speaker amplifier setup of claim 1, further comprising:
at least one speaker amplifier, wherein said speaker amplifier is capable of bidirectional digital communication with said speaker amplifier system panel; and
a communications network connecting said speaker amplifier system panel and said speaker amplifier, said network conveying digitally transmitted instructions from said speaker amplifier system panel to said speaker amplifier.

4. The automation system for speaker amplifier setup of claim 1, further comprising:
at least one speaker amplifier, wherein said speaker amplifier receives and audibly reproduces analog audio signals.

5. The automation system for speaker amplifier setup of claim 2, wherein said human interface subsystem further comprises:
a video display, whereupon said display output of said configuration status display routine can displayed;
a keyboard-type data entry device wherewith data and commands comprising keystrokes may be entered; and
a mouse-type data entry device, wherewith position data and mouse-click commands may be entered.

6. The automation system for speaker amplifier setup of claim 2, wherein said nonvolatile storage subsystem further comprises a disk drive, interface electronics, and storage-/retrieval-support operating system software.

7. The automation system for speaker amplifier setup of claim 2, wherein said communications subsystem further comprises a bidirectional communications port and interface electronics.

8. The automation system for speaker amplifier setup of claim 7, wherein said communications subsystem further comprises an RS-485 bidirectional differential serial peripheral communications port and interface electronics.

9. The automation system for speaker amplifier setup of claim 7, wherein said communications subsystem further comprises an IEEE-802 Ethernet® bidirectional serial peripheral communications port and interface electronics.

10. The automation system for speaker amplifier setup of claim 7, wherein said communications subsystem further comprises an RS-232 bidirectional single-ended serial peripheral communications port and interface electronics.

11. The automation system for speaker amplifier setup of claim 1, wherein said signal source further comprises:
a command transmittal routine;
a system monitor routine;
a system status report generator; and
a configuration status display routine for generating a display output, wherein said configuration status display is a representation of said commands and said system status reports.

12. The automation system for speaker amplifier setup of claim 11, wherein said command transmittal routine transmits a command that exerts control over said speaker amplifier system panel.

13. The automation system for speaker amplifier setup of claim 1, wherein said set of commands permits a multiplicity of command signals to be issued;

14. The automation system for speaker amplifier setup of claim 1, wherein each command signal issued from said signal source is directed to one digitally enabled system device.

15. The automation system for speaker amplifier setup of claim 1, wherein said speaker amplifier system panel senses, interprets, executes, and replies to those commands from said set of commands that are addressed uniquely to said speaker amplifier system panel.

16. The automation system for speaker amplifier setup of claim 2, wherein said nonvolatile storage subsystem further comprises a data backup and storage routine, wherein said data backup and storage routine records system status, as generated by said system status report generator, to said nonvolatile storage.

17. An automation system for speaker amplifier setup, comprising:
means for processing electronic signals;
means for communicating between said processing means and a speaker amplifier system panel; and
means for configuring said speaker amplifier system panel in response to signals from said processing means.

18. The speaker amplifier setup automation system of claim 17, further comprising means for interrogating said speaker amplifier system panel by an interrogation routine.

19. The speaker amplifier setup automation system of claim 17, further comprising means for recovering system configuration information from automated records of the status of a system panel maintained in nonvolatile storage media.

20. The speaker amplifier setup automation system of claim 17, further comprising means for visually representing information related to at least one of the identity, functional properties, and condition of said speaker amplifier system panel.

21. A method for configuring a speaker amplifier system panel, comprising:
executing a configuration status acquisition routine;
executing a configuration status report generator;
executing a configuration status display routine generating a display output that represents the acquired configuration status report;
generating a configuration change command; and
executing a command transmittal to a speaker amplifier system panel.

22. The method for configuring a speaker amplifier system panel of claim 21, further comprising:
executing a sequencing routine that can issue a multiplicity of command signals, wherein each command signal is directed to one speaker amplifier system panel and exercises at least one command function of an executable speaker amplifier system panel setup command routine.

23. The method for configuring a speaker amplifier system panel of claim 21, further comprising:
executing a data writing and reading routine, wherein the data writing and reading routine records and retrieves system status data in nonvolatile storage, as generated by the system status report generator.
